(19) United States
(12) Patent Application Publication
(10) Pub. No.: US 2026/0221106 A1
(43) Pub. Date: Jul. 30, 2026

(54) Display Apparatus Including Narrow Bezel

(71) Applicant: LG Display Co., Ltd., Seoul (KR)

(72) Inventors: Hwi Deuk Lee, Paju-si (KR); Eui Tae Kim, Paju-si (KR); Hong Sik Kim, Paju-si (KR); Ye Seul Han, Paju-si (KR); Kwang Hyun Choi, Paju-si (KR)

(21) Appl. No.: 19/447,957

(22) Filed: Jan. 13, 2026

(30) Foreign Application Priority Data
Jan. 24, 2025 (KR) 10-2025-0011683

(51) Int. Cl. G09G 3/3266

(52) U.S. Cl. CPC G09G 3/3266; G09G 2300/0819; G09G 2300/0842; G09G 2300/0861; G09G 2310/0286; G09G 2310/08; G09G 2320/0223; G09G 2330/021

(57) ABSTRACT

A display apparatus presented herein includes a display panel including a first bezel area and a second bezel area with a display area therebetween, gate drivers disposed along a first direction in the first bezel area, source drivers disposed along the first direction in the second bezel area, a plurality of gate clock supply lines disposed to extend in the first direction in the first bezel area and configured to supply gate clocks to the gate drivers, gate output link lines extending in a second direction intersecting with the first direction in output link regions of the display area and connecting gate outputs of the gate drivers based on the gate clocks to gate lines of the display panel, and gate clock link lines extending in the second direction in clock link regions of the display area and transferring the gate clocks to the gate clock supply lines.

### CROSS-REFERENCE TO RELATED APPLICATION

The present application claims priority to Republic of Korea Patent Application No. 10-2025-0011683, filed on January 24, 2025, which is hereby incorporated by reference in its entirety.

### BACKGROUND

### Field

The present disclosure relates to a display apparatus and particularly to, for example, without limitation, a display apparatus including a narrow bezel.

### Discussion of Related Art

In display apparatuses, a gate driver in panel (GIP) type where a gate driver is disposed in a bezel area, for example, a left bezel area and/or a right bezel area, has been known.

However, in a conventional GIP type, because a panel load such as an RC load applied to each gate clock line is very large, an RC delay of a gate clock increases. When the RC delay of the gate clock increases, a gate output may be distorted.

Such a limitation severely occurs in a large-screen display apparatus.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

To address the aforementioned limitation of the related art, embodiments of the present disclosure may provide a display apparatus which may decrease an RC delay of a gate clock in the display apparatus.

To achieve these objects and other advantages and in accordance with the purpose of the present disclosure, as embodied and broadly described herein, a display apparatus includes: a display panel including a first bezel area and a second bezel area disposed to face each other with a display area, including pixels, between the first bezel area and the second bezel area; a plurality of gate drivers disposed along a first direction in the first bezel area; a plurality of source drivers disposed along the first direction in the second bezel area; a plurality of gate clock supply lines disposed to extend in the first direction in the first bezel area and configured to supply gate clocks to the gate drivers; a plurality of gate output link lines extending in a second direction intersecting with the first direction in output link regions of the display area and configured to connect gate outputs of the plurality of the gate drivers based on the gate clocks to gate lines of the display panel; and a plurality of gate clock link lines extending in the second direction in clock link regions of the display area and configured to transfer the gate clocks, input from the outside, to the plurality of the gate clock supply lines.

In a further embodiment of the present disclosure, it is provided a display panel comprising: a first bezel area and a second bezel area disposed to face each other with a display area, including pixels, between the first bezel area and the second bezel area; a plurality of gate drivers disposed along a first direction in the first bezel area; a plurality of source drivers disposed along the first direction in the second bezel area; a plurality of gate clock supply lines disposed to extend in the first direction in the first bezel area and configured to supply gate clocks to the gate drivers; a plurality of gate output link lines extending in a second direction intersecting with the first direction in output link regions of the display area and configured to connect gate outputs of the plurality of the gate drivers based on the gate clocks to gate lines of the display panel; and a plurality of gate clock link lines extending in the second direction in clock link regions of the display area and configured to transfer the gate clocks, input from the outside, to the plurality of the gate clock supply lines, wherein, each of the plurality of gate drivers includes a plurality of gate units configured to generate gate outputs of different phases and supply the gate outputs to corresponding gate lines of the display panel.

### BRIEF DESCRIPTION OF THE DRAWINGS

The accompanying drawings, that may be included to provide a further understanding of the present disclosure and may be are incorporated in and constitute a part of this disclosure, illustrate embodiment(s) of the present disclosure and together with the description serve to explain various principles of the present disclosure. In the drawings:

FIG. 1 illustrates a display apparatus according to one or more embodiments of the present disclosure.

FIG. 2A and FIG. 2B illustrate a pixel circuit and a driving timing thereof according to one or more embodiments of the present disclosure.

FIG. 3 illustrates an example where a clock link region is disposed between two adjacent output link regions according to one or more embodiments of the present disclosure.

FIGS. 4A and 4B illustrate another example where a clock link region is disposed between two adjacent output link regions according to one or more embodiments of the present disclosure.

FIG. 5 illustrates an arrangement example of gate clock link lines according to one or more embodiments of the present disclosure.

FIG. 6 illustrates another arrangement example of gate clock link lines according to one or more embodiments of the present disclosure.

FIG. 7 illustrates an example where start carry transfer directions of gate drivers are set to be opposite to each other with respect to a center portion of a notch, according to one or more embodiments of the present disclosure.

FIG. 8 illustrates an example where start carry transfer directions of gate drivers are set to be equal to each other, according to a comparative example.

FIG. 9 illustrates an example where contact positions of a low resistance-high resistance double layer for compensating for a position-based RC delay deviation of a gate output are differently set according to one or more embodiments of the present disclosure.

FIGS. 10 and 11 describe the principle that an RC delay deviation between a gate output of a gate unit GU1 and a gate output of a gate unit GU1676 is compensated for according to one or more embodiments of the present disclosure.

### DETAILED DESCRIPTION

Hereinafter, embodiments of the present disclosure will be described in detail with reference to the accompanying drawings. In the disclosure, in adding reference numerals for elements in each drawing, it should be noted that like reference numerals already used to denote like elements in other drawings are used for elements wherever possible. In the following description, when the detailed description of the relevant known function or configuration is determined to unnecessarily obscure an important point of the present disclosure, the detailed description will be omitted or may be briefly provided.

Like reference numerals refer to like elements. Also, a thickness, a ratio, and a dimension of each element described herein may be illustrated to be partially enlarged or reduced for convenience of effective description. A scale of each element illustrated in the drawings of the present disclosure may have a scale which differs from a real scale, for convenience of description, and is not limited to a scale illustrated in the drawings.

In the present disclosure, when an arbitrary element (or a region, a layer, a portion, etc.) is described as “being on”, "being connected to", or "being coupled to" another element, this may denote that the arbitrary element may be directly on, connected or coupled to the other element, or a third element may be disposed therebetween.

The term "and/or" may include all of one or more combinations capable of being defined by relevant elements connected by this term.

Terms like a first and a second may be used to describe various elements, but the elements should not be limited by the terms. The terms may be used only as object for distinguishing an element from another element. For example, without departing from the technical idea and scope of the inventive concept, a first element may be referred to as a second element, and similarly, the second element may be referred to as the first element. The terms of a singular form may include plural forms unless referred to the contrary.

The terms "under", "below", "on", “near”, “adjacent to” and "above" may be used to describe a correlation between elements illustrated in the drawings. The terms may be a relative concept and may be described with respect to a direction illustrated in the drawings. For example, unless "just" or "direct" is used, one or more other elements may be disposed between the elements described by these terms. Spatially relative terms “below”, “beneath”, “lower”, “above”, “near”, “adjacent to” and “upper” may be used herein for easily describing a relationship between one device or elements and other devices or elements as illustrated in the drawings. Therefore, for example, "under” and "lower" may be opposite to "on" and "upper" with respect to a first device or element.

It should be understood that spatially relative terms are terms including different orientations of elements in use or operation, in addition to the orientation illustrated in the drawings. For example, if a device or element in the drawings is turned over, devices or elements described as being on the “below” or “beneath” sides of other elements may be placed “on” or “above” sides of the other elements. Therefore, the exemplary term “lower” may include both orientations of “lower” and “upper”. Likewise, the exemplary term “above” or “upper” may include both orientations of above and below.

It should be understood that the meaning of “include,” “comprise,” “including,” or “comprising,” may specify a property, a region, a fixed number, a step, a process, an element and/or a component, but does not exclude other properties, regions, fixed numbers, steps, processes, elements and/or components.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other, or may be carried out together in co-dependent relationship.

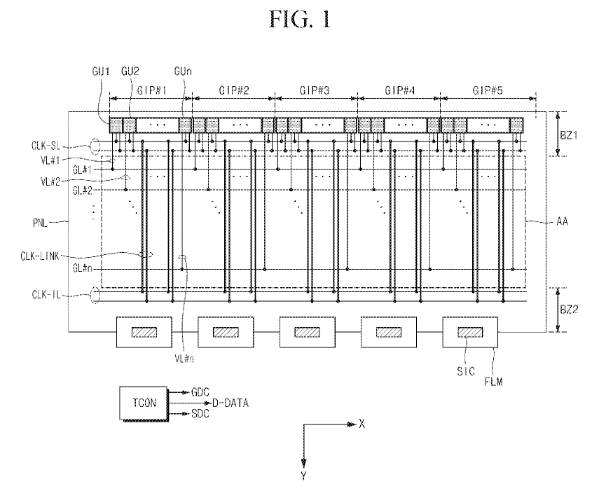

FIG. 1 illustrates a display apparatus according to one or more embodiments of the present disclosure.

As illustrated in FIG. 1, the display apparatus according to one or more embodiments of the present disclosure may include a display panel PNL, data drivers SIC, gate drivers GIP#1 to GIP#5, and a timing controller TCON.

The display panel PNL may include a display area (active area) AA which displays an image and a non-display area (non-active area) which is a bezel area. The non-display area may be disposed outside the display area AA along an edge of the display panel PNL.

The display area AA may display an input image corresponding to image data D-DATA, and the non-display area may include a bezel area, which does not display an image, of the display panel PNL. The bezel area may include a first bezel area BZ1 and a second bezel area BZ2, which are disposed to face each other with the display area AA therebetween. In a second direction Y as illustrated in FIG. 1, the first bezel area BZ1 may be referred to as an upper bezel area BZ1, and the second bezel area BZ2 may be referred to as a lower bezel area BZ2.

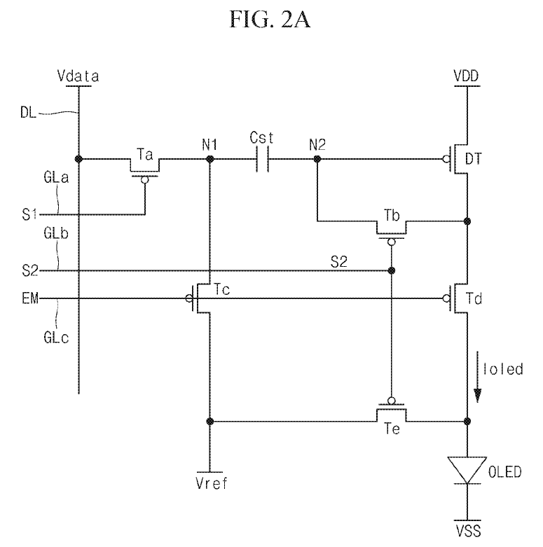

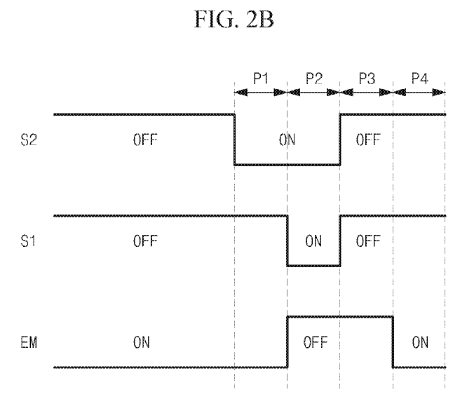

In the display area AA, a plurality of data lines (not shown in FIG. 1) extending in the second direction Y may intersect with a plurality of gate lines GL#1 to GL#n extending in a first direction X, and a pixel circuit illustrated in FIG. 2A may be disposed in each intersection area defined by intersections between the plurality of data lines and the plurality of gate lines. The pixel circuit, for example, may be connected to one data line and one gate line. The one gate line may include a first scan line, a second scan line, and an emission line. In this case, one gate output supplied to the one gate line may include a first scan signal, a second scan signal, and an emission signal.

In the display area AA, pixels adjacent to each other in the first direction X may configure a pixel row, and pixels adjacent to each other in the second direction Y may configure a pixel column. A plurality of pixel rows and a plurality of pixel columns may be provided in the display area AA.

A plurality of pixels may be grouped to configure one unit pixel. The one unit pixel may be configured for implementing various colors. When a pixel group for color implementation is defined as a unit pixel, one unit pixel may be configured to include a red (R) pixel, a green (G) pixel, and a blue (B) pixel, but is not limited thereto and may be configured to include a red (R) pixel, a green (G) pixel, a blue (B) pixel, and a white (W) pixel.

Each pixel may include a light emitting diode such as an OLED as a light emitting device. The light emitting device OLED may include an anode electrode, a cathode electrode, and an organic compound layer formed therebetween. The organic compound layer may include a hole injection layer (HIL), a hole transport layer (HTL), an emission layer (EML), an electron transport layer (ETL), and an electron injection layer (EIL), but is not limited thereto. When a pixel current flows in the light emitting device OLED, a hole passing through the hole transport layer (HTL) and an electron passing through the electron transport layer (ETL) may move to the emission layer (EML) to generate an exciton, and thus, the emission layer (EML) may emit visible light, but is not limited thereto. Also, the organic compound layer may be replaced with an inorganic compound layer.

A thin film transistor may be included in the pixel circuit, and the thin film transistor may be implemented to include low temperature polysilicon (LTPS) and/or oxide.

The gate drivers GIP#1 to GIP#5 may be disposed in plurality in the first direction X in the upper bezel area BZ1. The gate drivers GIP#1 to GIP#5 may generate a gate output which is to be supplied to the gate lines GL#1 to GL#n, based on a multi-feeding scheme based on a gate timing control signal GDC input from the timing controller TCON.

Each of the gate drivers GIP#1 to GIP#5 may include n number of gate units GU1 to GUn so as to drive n number of gate lines GL#1 to GL#n. The n gate units GU1 to GUn may generate gate outputs of different phases and may supply the gate outputs to the gate lines GL#1 to GL#n.

To implement the multi-feeding scheme, gate outputs of the same phase may be supplied from GIP#1, GIP#2, GIP#3, GIP#4, and GIP#5 to different positions of the same gate line GL#1 to GL#n.

For example, first gate outputs generated by the gate unit GU1 of the gate drivers GIP#1, GIP#2, GIP#3, GIP#4, and GIP#5 may be supplied to five different positions of the first gate line GL#1, second gate outputs generated by the gate unit GU2 of the gate drivers GIP#1, GIP#2, GIP#3, GIP#4, and GIP#5 may be supplied to five different positions of the second gate line GL#2, and third gate outputs generated by the gate unit GU3 of the gate drivers GIP#1, GIP#2, GIP#3, GIP#4, and GIP#5 may be supplied to five different positions of the gate line GL#3. Likewise, n^{th} gate outputs generated by the gate unit GUn of the gate drivers GIP#1, GIP#2, GIP#3, GIP#4, and GIP#5 may be supplied to five different positions of the n^{th} gate line GL#n. Based on such multi-feeding, a panel position-based RC delay deviation of gate outputs of the same phase may be reduced.

Each of the source drivers SIC may be implemented as an integrated circuit (IC) which is mounted on a conductive film FLM and is bonded to the lower bezel area BZ2. The source drivers SIC may be disposed in plurality in the first direction X in the lower bezel area BZ2. The source drivers SIC may be disposed to face the gate drivers GIP#1 to GIP#5 with the display area AA therebetween. The gate drivers GIP#1 to GIP#5 and the source drivers SIC may be divisionally disposed in the upper bezel area BZ1 and the lower bezel area BZ2, and thus, may prevent a bezel area from being excessively widened in an upper portion or a lower portion.

Each of the source drivers SIC may convert image data D-DATA into data voltages, based on a source timing control signal SDC input from the timing controller TCON, and may supply the data voltages to the data lines of the display panel PNL. Each of the source drivers SIC may include a shift register, a latch, a digital-to-analog converter (DAC), and an output buffer.

A plurality of gate clock supply lines CLK-SL may be disposed in the upper bezel area BZ1. The plurality of gate clock supply lines CLK-SL may be disposed to extend in the first direction X in the upper bezel area BZ1 and may supply gate clocks for the gate outputs to the gate drivers GIP#1 to GIP#5.

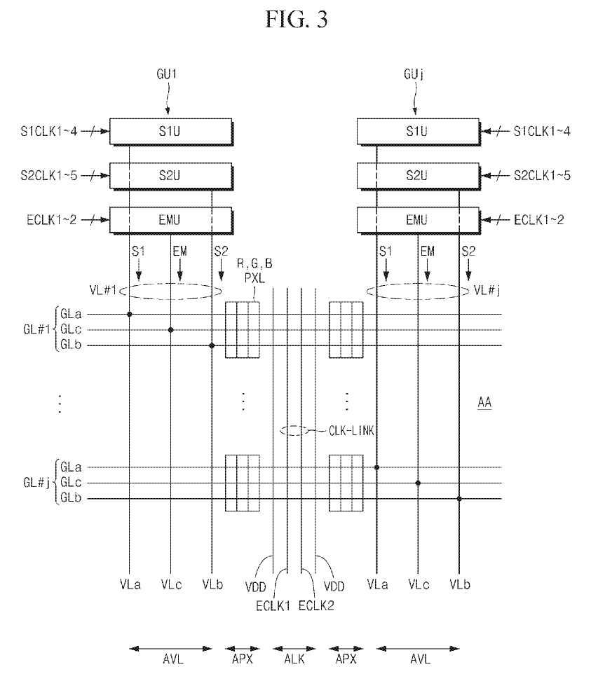

The display area AA may further include output link regions (see AVL of FIG. 3) and clock link regions (see ALK of FIG. 3), in addition to pixel areas where pixel circuits are disposed.

Gate output link lines VL#1 to VL#n may be disposed in the output link regions AVL. The gate output link lines VL#1 to VL#n may extend in the second direction Y intersecting with the first direction X and may connect gate outputs of the gate drivers GIP#1 to GIP#5 to the gate lines GL#1 to GL#n of the display panel PNL. Gate output link lines VL#1 to VL#n may be multi-connected to different positions of a same gate line. A gate output of a same phase may be supplied to the same gate line through gate output link lines VL#1 to VL#n multi-connected.

For example, the first gate outputs generated by the gate unit GU1 of the gate drivers GIP#1, GIP#2, GIP#3, GIP#4, and GIP#5 may be supplied to five different positions of the first gate line GL#1 through the first gate output link lines VL#1, the second gate outputs generated by the gate unit GU2 of the gate drivers GIP#1, GIP#2, GIP#3, GIP#4, and GIP#5 may be supplied to five different positions of the second gate line GL#2 through the second gate output link lines VL#2, and the third gate outputs generated by the gate unit GU3 of the gate drivers GIP#1, GIP#2, GIP#3, GIP#4, and GIP#5 may be supplied to five different positions of the gate line GL#3 through the gate output link lines VL#3. Likewise, the n^{th} gate outputs generated by the gate unit GUn of the gate drivers GIP#1, GIP#2, GIP#3, GIP#4, and GIP#5 may be supplied to five different positions of the n^{th} gate line GL#n through the n^{th} gate output link lines VL#n.

Gate clock link lines CLK-LINK may be disposed in the clock link regions. The gate clock link lines CLK-LINK may be disposed to extend in the second direction Y and may transfer gate clocks, input from the outside, to the gate clock supply lines CLK-SL disposed in the upper bezel area BZ1.

A plurality of gate clock input lines CLK-IL may be further disposed in the lower bezel area BZ2. The gate clock input lines CLK-IL may be disposed to extend in the first direction X in the lower bezel area BZ2 and may be connected to the gate clock link lines CLK-LINK of the clock link regions. The gate clock input lines CLK-IL may receive the gate clocks from the outside, and then, may transfer the gate clocks to the gate clock link lines CLK-LINK.

Gate clock link lines CLK-LINK disposed in the clock link regions of the display area AA may be multi-connected to different positions of the same clock supply line CLK-SL disposed in the first bezel area BZ1. Gate clocks of the same phase may be transferred to the same clock supply line CLK-SL disposed in the upper bezel area BZ1 through the multi-connected gate clock link lines CLK-LINK.

Because a panel load is dispersed by a multi-position connection configuration of a gate clock link line CLK-LINK targeted for the same clock supply line CLK-SL, a panel position-based RC delay deviation of gate clocks having the same phase may decrease. Gate clock link lines CLK-LINK for reducing a panel position-based RC delay deviation of gate clocks having the same phase may be elements which may not be predicted from a GIP-type display apparatus of the related art.

The timing controller TCON may supply digital image data D-DATA, transferred from a host system, to the source drivers SIC. The timing controller TCON may receive a timing signal such as a vertical synchronization signal, a horizontal synchronization signal, a data enable signal, and a dot clock from the host system to generate timing control signals for controlling operation timings of the source drivers SIC and the gate drivers GIP#1 to GIP#5.

The timing controller TCON may generate a gate timing control signal GDC for controlling the operation timings of the gate drivers GIP#1 to GIP#5 and a source timing control signal SDC for controlling the operation timing of the source drivers SIC.

The host system may be an application processor (AP) applied to mobile devices, wearable devices, virtual/augmented reality (VR/AR) devices, ambient intelligence devices and in-vehicle devices. Also, the host system may be a main board of television systems, set-top box, navigation systems, personal computers, and home theater systems, but is not limited thereto.

FIG. 2A and FIG. 2B illustrate a pixel circuit and a driving timing thereof.

As illustrated in FIG. 2A, a pixel circuit according to one or more embodiments of the present disclosure may include transistors Ta, Tb, Tc, Td, and Te, a storage capacitor Cst, a driving transistor DT and a light emitting device OLED. The transistors Ta, Tb, Tc, Td, and Te, the storage capacitor Cst and the driving transistor DT may be connected to the light emitting device OLED. An example illustrated in FIG. 2A represents 6T1C structure that where six transistors and one capacitor are disposed, but embodiments of the present disclosure are not limited to this. For example, 2T1C structure, 3T1C structure, 4T1C structure, 4T2C structure and etc. are also possible. And more or less transistors and capacitors could be included.

The transistor Ta may include a gate electrode receiving a first scan signal S1 through a first sub-scan line GLa, a first electrode receiving a data voltage Vdata through a data line DL, and a second electrode connected to a first node N1. The transistor Ta may transfer the data voltage Vdata to the first node N1 in response to the first scan signal S1 of a turn-on level.

The storage capacitor Cst may be connected between the first node N1 and a second node N2 and may store a difference voltage between a voltage of the first node N1 and a voltage of the second node N2.

The driving transistor DT may include a gate electrode connected to the second node N2, a first electrode receiving a high-level driving voltage VDD, and a second electrode electrically connected to the light emitting device OLED. The second electrode of the driving transistor DT may be electrically connected to the anode electrode of the light emitting device OLED. The driving transistor DT may be supplied with the high-level driving voltage VDD to generate a driving current corresponding to the voltage of the second node N2. A magnitude of the driving current may be differently generated based on the voltage of the second node N2.

The Tb transistor may include a gate electrode receiving a second scan signal S2 through a second sub-scan line GLb, a first electrode connected to the second electrode of the driving transistor DT and electrically connected to the light emitting device OLED, and a second electrode connected to the second node N2. The Tb transistor may electrically connect the second electrode of the driving transistor DT to the second node N2 in response to the second scan signal S2 of a turn-on level. That is, while the Tb transistor is being turned on, the second electrode and the gate electrode of the driving transistor DT may be short-circuited therebetween, and thus, the driving transistor DT may operate like a diode.

The transistor Tc may include a gate electrode receiving an emission signal EM through an emission line GLc, a first electrode receiving a reference voltage Vref, and a second electrode connected to the first node N1. The transistor Tc may supply the reference voltage Vref to the first node N1 to initialize the first node N1, in response to the emission signal EM of a turn-on level.

The transistor Td may include a gate electrode receiving the emission signal EM, a first electrode connected to the second electrode of the driving transistor DT, and a second electrode connected to the anode electrode of the light emitting device OLED. The transistor Td may supply the driving current, generated by the driving transistor DT, to the light emitting device OLED in response to the emission signal EM of a turn-on level.

The transistor Te may include a gate electrode receiving second scan signal S2, a first electrode receiving the reference voltage Vref, and a second electrode connected to the anode electrode of the light emitting device OLED. The transistor Te may supply the reference voltage Vref to the anode electrode of the light emitting device OLED to initialize the anode electrode of the light emitting device OLED, in response to the second scan signal S2 of a turn-on level.

As illustrated in FIG. 2B, an operation sequence of the pixel circuit may include an initialization period P1, a programming period P2, a holding period P3, and an emission period P4.

In the initialization period P1, the second scan signal S2 and the emission signal EM may be input at a turn-on level, and the first node N1, the second node N2, and the anode electrode of the light emitting device OLED may be supplied with the reference voltage Vref and may thus be initialized.

In the programming period P2, a threshold voltage Vth of the driving transistor DT may be sampled, and the data voltage Vdata may be programmed in the second node N2. In detail, in the programming period P2, the first scan signal S1 and the second scan signal S2 may be input at a turn-on level, and thus, the data voltage Vdata may be supplied to the first node N1, and a voltage obtained by summating a driving voltage VDD and the threshold voltage Vth of the driving transistor DT may be supplied to the second node N2 and may be stored in the storage capacitor Cst.

In the holding period P3, the first and second scan signals S1 and S2 and the emission signal EM may be input at a turn-off level, and thus, the first and second nodes N1 and N2 connected to the storage capacitor Cst may be floated.

In the emission period P4, the emission signal EM may be input at a turn-on level, and thus, the driving transistor DT may generate the driving current to supply the driving current to the light emitting device OLED, based on a voltage level of the second node N2 connected to the storage capacitor Cst.

FIG. 3 illustrates an example where a clock link region ALK is disposed between two adjacent output link regions AVLs.

Referring to FIG. 3, each gate unit GU1 or GUj (where j may be a natural number of 2 or more) may include a first scan unit S1U which outputs a first scan signal S1, a second scan unit S2U which outputs a second scan signal S2, and an emission unit EMU which outputs an emission signal EM.

In the display area AA, when an output link region AVL where first gate output link lines VL#1 are disposed is adjacent to an output link region AVL where second gate output link lines VL#2 are disposed, a pixel area APX where RGB pixel circuits are disposed, a clock link region ALK where gate clock link lines CLK-LINK are disposed, and a further pixel area APX where RGB pixel circuits are disposed may be disposed between the output link regions AVL. In addition, as illustrated in FIG. 3, the clock link region ALK may be disposed between the two adjacent pixel areas APX. The pixel area APX may be disposed between a corresponding output link region AVL and a corresponding clock link region ALK.

The first scan unit S1U included in the gate unit GU1 may selectively receive two first gate clocks among four-phase first scan clocks S1CLK1 to S1CLK4 (that is, S1CLK1~4 as illustrated on the left of FIG. 3) to generate the first scan signal S1, and then, may supply the first scan signal S1 to a first sub-scan line GLa of a first gate line GL#1 through an output link line VLa of the first gate output link lines VL#1.

The second scan unit S2U included in the gate unit GU1 may selectively receive two second gate clocks among five-phase second scan clocks S2CLK1 to S2CLK5 (that is, S2CLK1~5 as illustrated on the left of FIG. 3) to generate the second scan signal S2, and then, may supply the second scan signal S2 to a second sub-scan line GLb of the first gate line GL#1 through an output link line VLb of the first gate output link lines VL#1.

The emission unit EMU included in the gate unit GU1 may receive two-phase emission clocks ECLK1 and ECLK2 (that is, ECLK1~2 as illustrated on the left of FIG. 3) to generate the emission signal EM, and then, may supply the emission signal EM to an emission line GLc of the first gate line GL#1 through an output link line VLc of the first gate output link lines VL#1.

The first scan unit S1U included in the gate unit GUj may selectively receive two first gate clocks among the four-phase first scan clocks S1CLK1 to S1CLK4 (that is, S1CLK1~4 as illustrated on the right of FIG. 3) to generate the first scan signal S1, and then, may supply the first scan signal S1 to a first sub-scan line GLa of a gate line GL#j through an output link line VLa of gate output link lines the VL#j.

The second scan unit S2U included in the gate unit GUj may selectively receive two second gate clocks among the five-phase second scan clocks S2CLK1 to S2CLK5 (that is, S2CLK1~5 as illustrated on the right of FIG. 3) to generate the second scan signal S2, and then, may supply the second scan signal S2 to a second sub-scan line GLb of the gate line GL#j through an output link line VLb of the gate output link lines VL#j.

The emission unit EMU included in the gate unit GUj may receive the two-phase emission clocks ECLK1 and ECLK2 (that is, ECLK1~2 as illustrated on the right of FIG. 3) to generate the emission signal EM, and then, may supply the emission signal EM to an emission line GLc of the gate line GL#j through an output link line VLc of the gate output link lines VL#j.

The four-phase first scan clocks S1CLK1 to S1CLK4, the five-phase second scan clocks S2CLK1 to S2CLK5, and the two-phase emission clocks ECLK1 and ECLK2 may be supplied to a gate driver through gate clock link lines CLK-LINK disposed in a plurality of clock link regions ALK of the display area AA. For example, the two-phase emission clocks ECLK1 and ECLK2 may be supplied to corresponding units of the gate unit GU1 and the gate unit GUj through the gate clock link lines CLK-LINK disposed in the clock link region ALK via gate clock supply lines (not shown) of the upper bezel area. As can be noted, the description with respect to the gate units GU1 and GUj is just exemplary and can also be applied to other gate units similarly.

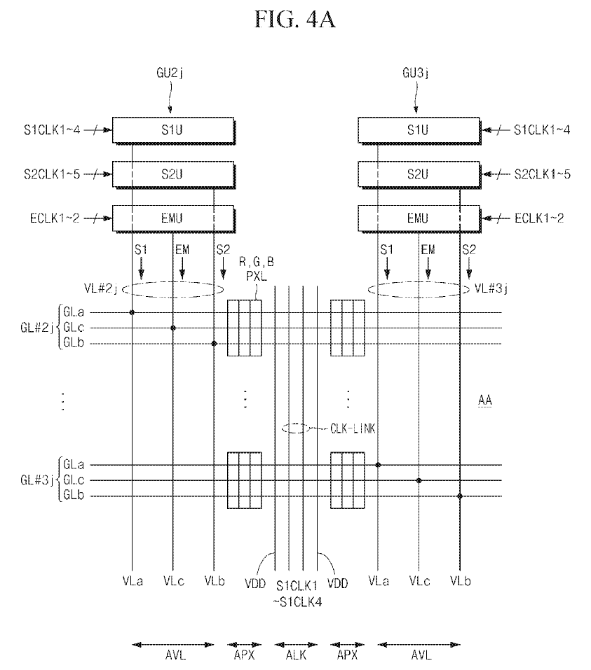

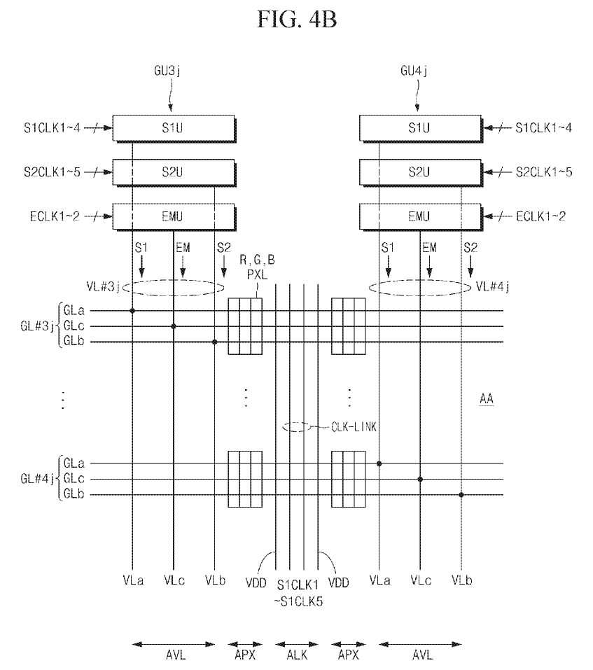

FIGS. 4A and 4B illustrate another example where a clock link region is disposed between two adjacent output link regions.

Referring to FIGS. 4A and 4B, each gate unit GU2j, GU3j, or GU4j may include a first scan unit S1U which outputs a first scan signal S1, a second scan unit S2U which outputs a second scan signal S2, and an emission unit EMU which outputs an emission signal EM.

As illustrated in FIG. 4A, in the display area AA, when an output link region AVL where second gate output link lines VL#2j are disposed is adjacent to an output link region AVL where third gate output link lines VL#3j are disposed, a pixel area APX where RGB pixel circuits are disposed, a clock link region ALK where gate clock link lines CLK-LINK are disposed, and a further pixel area APX where RGB pixel circuits are disposed may be disposed between the output link regions AVL. In addition, as illustrated in FIG. 4A, the clock link region ALK may be disposed between the two adjacent pixel areas APX.

Moreover, as illustrated in FIG. 4B, in the display area AA, when an output link region AVL where third gate output link lines VL#3j is disposed are adjacent to an output link region AVL where fourth gate output link lines VL#4j are disposed, a pixel area APX where RGB pixel circuits are disposed, a clock link region ALK where gate clock link lines CLK-LINK are disposed, and a further pixel area APX where RGB pixel circuits are disposed may be disposed between the output link regions AVL. In addition, as illustrated in FIG. 4B, the clock link region ALK may be disposed between the adjacent pixel areas APX.

The first scan unit S1U included in the gate unit GU2j may selectively receive two first gate clocks among four-phase first scan clocks S1CLK1 to S1CLK4 (that is, S1CLK1~4 as illustrated on the left of FIG. 4A) to generate the first scan signal S1, and then, may supply the first scan signal S1 to a first sub-scan line GLa of a gate line GL#2j through an output link line VLa of the second gate output link lines VL#2j.

The second scan unit S2U included in the gate unit GU2j may selectively receive two second gate clocks among five-phase second scan clocks S2CLK1 to S2CLK5 (that is, S2CLK1~5 as illustrated on the left of FIG. 4A) to generate the second scan signal S2, and then, may supply the second scan signal S2 to a second sub-scan line GLb of a gate line GL#2j through an output link line VLb of the second gate output link lines VL#2j.

The emission unit EMU included in the gate unit GU2j may receive two-phase emission clocks ECLK1 and ECLK2 (that is, ECLK1~2 as illustrated on the left of FIG. 4A) to generate the emission signal EM, and then, may supply the emission signal EM to an emission line GLc of the gate line GL#2j through an output link line VLc of the second gate output link lines VL#2j.

The first scan unit S1U included in the gate unit GU3j may selectively receive two first gate clocks among the four-phase first scan clocks S1CLK1 to S1CLK4 (that is, S1CLK1~4 as illustrated on the right of FIG. 4A) to generate the first scan signal S1, and then, may supply the first scan signal S1 to a first sub-scan line GLa of a gate line GL#3j through an output link line VLa of the third gate output link lines VL#3j.

The second scan unit S2U included in the gate unit GU3j may selectively receive two second gate clocks among the five-phase second scan clocks S2CLK1 to S2CLK5 (that is, S2CLK1~5 as illustrated on the right of FIG. 4A) to generate the second scan signal S2, and then, may supply the second scan signal S2 to a second sub-scan line GLb of the gate line GL#3j through an output link line VLb of the third gate output link lines VL#3j.

The emission unit EMU included in the gate unit GU3j may receive the two-phase emission clocks ECLK1 and ECLK2 (that is, ECLK1~2 as illustrated on the right of FIG. 4A) to generate the emission signal EM, and then, may supply the emission signal EM to an emission line GLc of the gate line GL#3j through an output link line VLc of the third gate output link lines VL#3j.

The first scan unit S1U included in the gate unit GU4j may selectively receive two first gate clocks among the four-phase first scan clocks S1CLK1 to S1CLK4 (that is, S1CLK1~4 as illustrated on the left of FIG. 4B) to generate the first scan signal S1, and then, may supply the first scan signal S1 to a first sub-scan line GLa of a gate line GL#4j through an output link line VLa of the fourth gate output link lines VL#4j.

The second scan unit S2U included in the GU4j may selectively receive two second gate clocks among the five-phase second scan clocks S2CLK1 to S2CLK5 (that is, S2CLK1~5 as illustrated on the left of FIG. 4B) to generate the second scan signal S2, and then, may supply the second scan signal S2 to a second sub-scan line GLb of the gate line GL#4j through an output link line VLb of the fourth gate output link lines VL#4j.

The emission unit EMU included in the GU4j may receive the two-phase emission clocks ECLK1 and ECLK2 to generate the emission signal EM, and then, may supply the emission signal EM to an emission line GLc of the gate line GL#4j through an output link line VLc of the fourth gate output link lines VL#4j.

The four-phase first scan clocks S1CLK1 to S1CLK4, the five-phase second scan clocks S2CLK1 to S2CLK5, and the two-phase emission clocks ECLK1 and ECLK2 may be supplied to gate drivers through gate clock link lines CLK-LINK disposed in a plurality of clock link regions ALK of the display area AA.

For example, as in FIG. 4A, the four-phase first scan clocks S1CLK1 to S1CLK4 may be supplied to corresponding units of the gate unit GU2j and the gate unit GU3j through the gate clock link lines CLK-LINK disposed in the clock link region ALK via gate clock supply lines (not shown) of the upper bezel area.

Moreover, as in FIG. 4B, the five-phase second scan clocks S2CLK1 to S2CLK5 may be supplied to corresponding units of the gate unit GU3j and the gate unit GU4j through the gate clock link lines CLK-LINK disposed in the clock link region ALK via gate clock supply lines (not shown) of the upper bezel area.

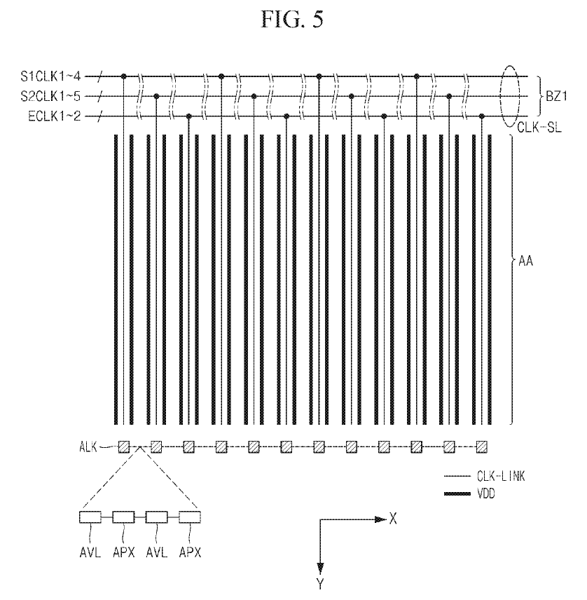

FIG. 5 illustrates an arrangement example of gate clock link lines.

Referring to FIG. 5, gate clock link lines CLK-LINK disposed in clock link regions ALK of a display area AA may be multi-connected to different positions of the same clock supply line disposed in the upper bezel area BZ1. Gate clocks S1CLK, S2CLK, and ECLK of the same phase may be transferred to the same clock supply line CLK-SL disposed in the upper bezel area BZ1 through the multi-connected gate clock link lines CLK-LINK, and thus, RC loads of gate clock lines may be dispersed.

One of clock link regions ALK may be disposed between two adjacent output link regions AVL, for the multi-arrangement of the gate clock link lines CLK-LINK in the display area AA.

In each of the clock link regions ALK of the display area AA, a first power line and a second power line to which a high-level driving voltage VDD is supplied may be further disposed with the gate clock link lines CLK-LINK therebetween. The high-level driving voltage VDD may be a high-level power voltage supplied to a pixel circuit. The first power line and the second power line may be disposed in the second direction Y.

The first power line and the second power line may be disposed between one of data lines of the display panel and at least one of the gate clock link lines CLK-LINK. Each of the first power line and the second power line may prevent the gate clock link lines CLK-LINK from being disposed adjacent to data lines, and thus, may minimize or at least reduce a coupling effect between the data lines and the gate clock link lines CLK-LINK. Accordingly, gate clocks may be prevented from being distorted by coupling noise caused by an electric potential variation of each of the data lines.

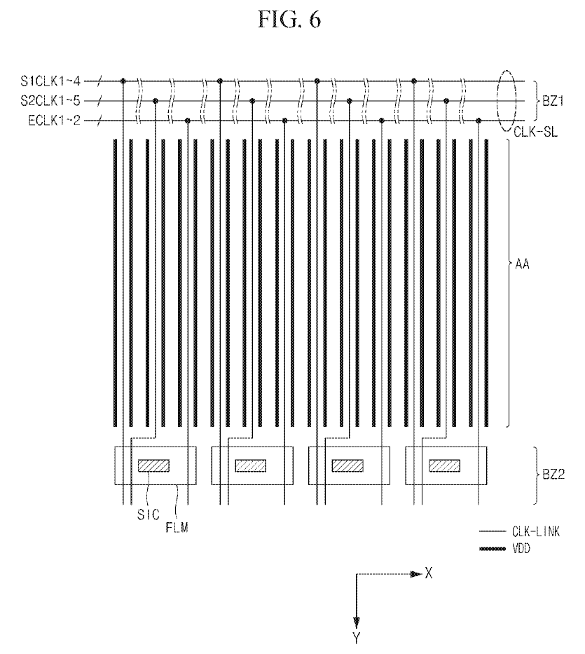

FIG. 6 illustrates another arrangement example of gate clock link lines.

Referring to FIG. 6, the gate clock input lines CLK-IL of FIG. 1 may be omitted in a lower bezel area BZ2, and thus, the lower bezel area BZ2 may be more reduced. Instead, the plurality of gate clock link lines may further extend to the second bezel area BA2 and connected to an external clock source via a conductive film. In this case, gate clock link lines CLK-LINK may further extend to the lower bezel area BZ2, a source driver SIC may be mounted on a conductive film FLM and the gate clock link lines CLK-LINK may be connected to an external clock source (for example, a timing controller) through a residual dummy area.

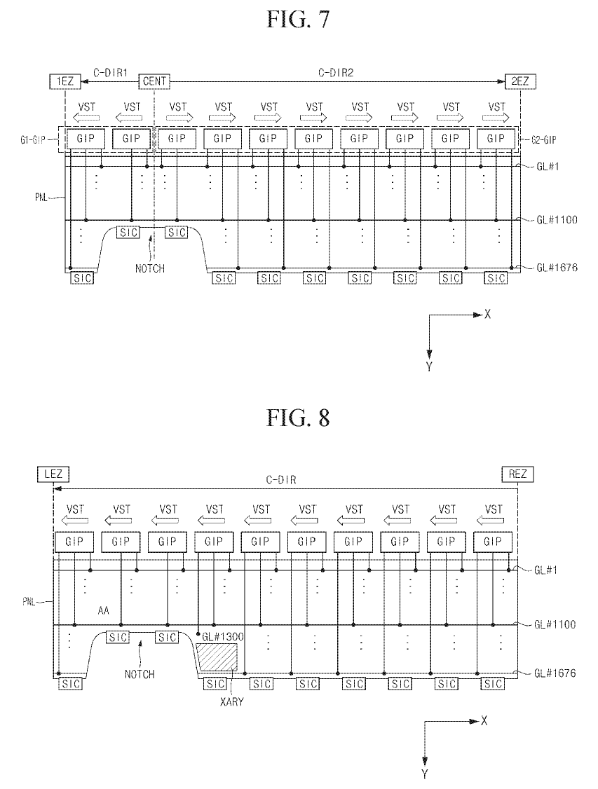

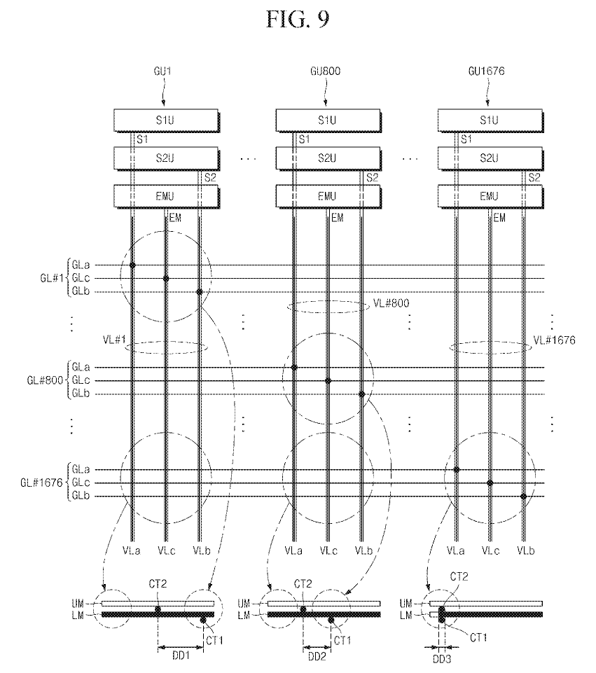

FIG. 7 illustrates an example where start carry transfer directions of gate drivers are set to be opposite to each other with respect to a center portion of a notch, according to one or more embodiments of the present disclosure. FIG. 8 illustrates an example where start carry transfer directions of gate drivers are set to be equal to each other, according to a comparative example.

Referring to FIGS. 7 and 8, the gate drivers may be connected to the gate lines, where a first gate line GL#1, a 1100^{th} gate line GL#1100 and a 1676^{th} gate line GL#1676 are shown as examples.

Referring to FIG. 7, a display panel PNL may further include a notch NOTCH where a panel resolution (i.e., a vertical resolution of a panel) in a second direction Y is relatively less than a normal area. The notch NOTCH may denote a recessed space of the display panel PNL. The notch NOTCH may be symmetrical in a first direction X with respect to a center portion CENT.

Gate drivers GIP may be divided into first-group gate drivers G1-GIP disposed at a first side with respect to the center portion CENT of the notch NOTCH and second-group gate drivers G2-GIP disposed at a second side opposite to the first side with respect to the center portion CENT of the notch NOTCH. In the first-group gate drivers G1-GIP, a start carry transfer direction VST for an operation activation of the first-group gate drivers G1-GIP is from the center portion CENT to a left edge portion 1EZ of the display panel PNL (as illustrated by a first carry transfer direction C-DIR1), and in the second-group gate drivers G2-GIP, a start carry transfer direction VST for an operation activation of the second-group gate drivers G2-GIP is from the center portion CENT to a right edge portion 2EZ of the display panel PNL (as illustrated by a second carry transfer direction C-DIR2).

In this case, as in FIG. 8, a start carry transfer direction VST for an operation activation of the first-group gate drivers G1-GIP is the same as a start carry transfer direction VST for an operation activation of the second-group gate drivers G2-GIP, and thus a link-unable region XARY incapable of connections between gate output link lines and gate lines may be formed near the notch NOTCH. Referring to FIG. 8, a start carry transfer direction VST for an operation activation of all the gate drivers GIP is from a right edge portion REZ of the display panel PNL to a left edge portion LEZ of the of the display panel PNL (as illustrated by a carry transfer direction C-DIR).

The link-unable region XARY may be supplied with a gate output through adjacent output link lines through multi-feeding. However, because the link-unable region XARY is relatively greater in RC delay than link-enable regions, the image quality of the link-unable region XARY may be degraded.

On the other hand, as in FIG. 7, when the start carry transfer direction VST for an operation activation of the first-group gate drivers G1-GIP is opposite to the start carry transfer direction VST for an operation activation of the second-group gate drivers G2-GIP, the link-unable region XARY incapable of connections between the gate output link lines and the gate lines may not be formed near the notch NOTCH.

The start carry transfer direction VST of the first-group gate drivers G1-GIP may be toward the left edge portion 1EZ of the display panel PNL from the center portion CENT of the notch NOTCH. Also, the start carry transfer direction VST of the second-group gate drivers G2-GIP may be toward a right edge portion 2EZ of the display panel PNL from the center portion CENT of the notch NOTCH.

FIG. 9 illustrates an example where contact positions of a low resistance-high resistance double layer for compensating for a position-based RC delay deviation of a gate output are differently set.

Referring to FIG. 9, a gate unit GU1 may supply first gate outputs S1, S2, and an emission signal EM to a first gate line GL#1 (i.e., GLa, GLb, and GLc) through first gate output link lines VL#1.

A gate unit GU800 may supply 800^{th} gate outputs S1, S2, and an emission signal EM to an 800^{th} gate line GL#800 (i.e., GLa, GLb, and GLc) through 800^{th} gate output link lines VL#800.

A gate unit GU1676 may supply 1676^{th} gate outputs S1, S2, and an emission signal EM to a 1676^{th} gate line GL#1676 (i.e., GLa, GLb, and GLc) through 1676^{th} gate output link lines VL#1676.

For example, when a gate output link line is implemented as a single layer, an RC load applied to the gate output link line may be greater in VL#800 than VL#1 and may be greater in VL#1676 than VL#800.

To compensate for an RC load difference between gate output link lines, lengths of the gate output link lines may be designed to be equal to one another, each of the gate output link lines may be designed as a double layer between a high-resistance link line LM and a low-resistance link line UM, and a contact position of the high-resistance link line LM and the low-resistance link line UM may be differently set between the gate output link lines.

A resistance of the low-resistance link line UM may be less than that of the high-resistance link line LM, and the low-resistance link line UM and the high-resistance link line LM may overlap each other with an insulation layer therebetween. The low-resistance link line UM may include a low-resistance material, and the high-resistance link line LM may include a high-resistance material. The low-resistance link line UM and the high-resistance link line LM may have the same line width. Alternatively, the low-resistance link line UM and the high-resistance link line LM may have different line widths, which may be varied according to actual requirements.

The first gate outputs S1, S2, and EM may be connected to the low-resistance link lines UM of the first gate output link lines VL#1. The high-resistance link lines LM of the first gate output link lines VL#1 may be connected to the first gate line GL#1 through a first contact portion CT1 and may be connected to the low-resistance link lines UM of the first gate output link lines VL#1 through a second contact portion CT2. In the first gate output link lines VL#1, an interval between the first contact portion CT1 and the second contact portion CT2 determining an RC load may be DD1.

The 800^{th} gate outputs S1, S2, and EM may be connected to the low-resistance link lines UM of the 800^{th} gate output link lines VL#800. The high-resistance link lines LM of the 800^{th} gate output link lines VL#800 may be connected to the 800^{th} gate line GL#800 through the first contact portion CT1 and may be connected to the low-resistance link lines UM of the 800^{th} gate output link lines VL#800 through the second contact portion CT2. In the 800^{th} gate output link lines VL#800, an interval between the first contact portion CT1 and the second contact portion CT2 determining an RC load may be DD2 which is less than the DD1.

The 1676^{th} gate outputs S1, S2, and EM may be connected to the low-resistance link lines UM of the 1676^{th} gate output link lines VL#1676. The high-resistance link lines LM of the 1676^{th} gate output link lines VL#1676 may be connected to the 1676^{th} gate line GL#1676 through the first contact portion CT1 and may be connected to the low-resistance link lines UM of the 1676^{th} gate output link lines VL#1676 through the second contact portion CT2. In the 1676^{th} gate output link lines VL#1676, an interval between the first contact portion CT1 and the second contact portion CT2 determining an RC load may be DD3 which is less than the DD2.

Because an interval between the first contact portion CT1 and the second contact portion CT2 is differentially designed between the gate output link lines like DD1, DD2, and DD3, an RC load difference occurring between the gate output link lines may be compensated for.

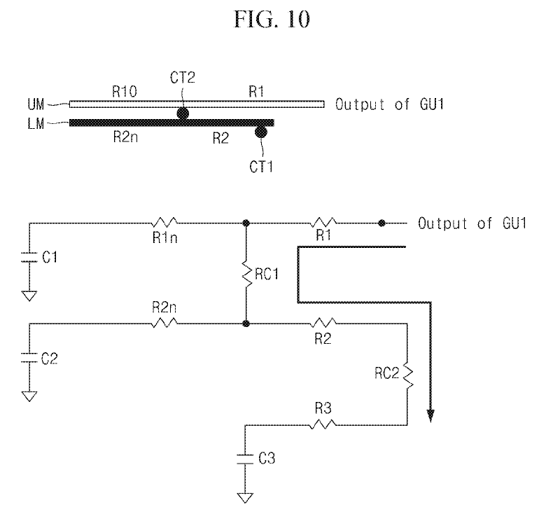

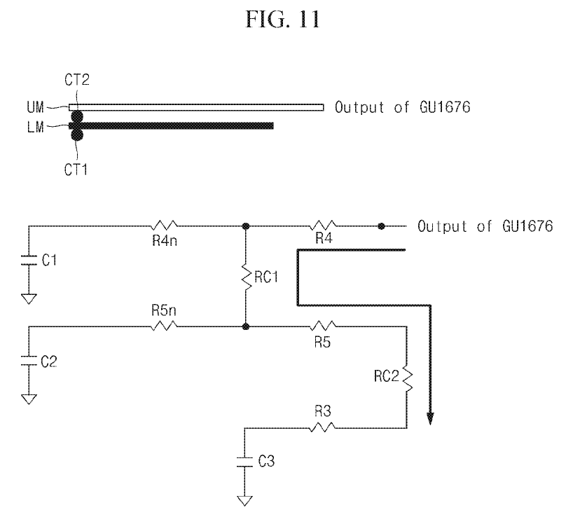

FIGS. 10 and 11 describe the principle that an RC delay deviation between a gate output of a gate unit GU 1 and a gate output of a gate unit GU1676 is compensated for.

Referring to FIG. 10, a total resistance Rt of first gate output link lines VL#1 for transferring a gate output of a gate unit GU1 may be “R1+Rc1+R2+Rc2”, a total capacitance Ct of the first gate output link lines VL#1 may be “C1+C2+C3”, and a total RC may be “(R1+Rc1+R2+Rc2) * (C1+C2+C3)”.

Referring to FIG. 11, a total resistance Rt of 1676^{th} gate output link lines VL#1676 for transferring a gate output of a gate unit GU1676 may be “R4+Rc1+R5+Rc2”, a total capacitance Ct of the 1676^{th} gate output link lines VL#1676 may be “C1+C2+C3”, and a total RC may be “(R4+Rc1+R5+Rc2) * (C1+C2+C3)”.

Referring to FIGS. 10 and 11, because the total capacitance Ct of the first gate output link lines VL#1 is equal to the total capacitance Ct of the 1676^{th} gate output link lines VL#1676, as “R1+R2” and “R4+R5” are adjusted, an RC load difference between the first gate output link lines VL#1 and the 1676^{th} gate output link lines VL#1676 may be compensated for.

To this end, when the interval DD1 between the first contact portion CT1 and the second contact portion CT2 is designed to be relatively large in the first gate output link lines VL#1, and the interval DD3 between the first contact portion CT1 and the second contact portion CT2 is designed to be relatively small in the 1676^{th} gate output link lines VL#1676, “R1+R2” and “R4+R5” may be similar to each other, and an RC load difference between the first gate output link lines VL#1 and the 1676^{th} gate output link lines VL#1676 may be compensated for at a similar level.

The display apparatus according to one or more embodiments of the present disclosure may decrease an RC delay of a gate clock to enhance display quality.

The effects according to the present disclosure are not limited to those in the above examples, and other various effects may be understood by that ordinary skill in the art according to the content included in the present disclosure.

While the present disclosure has been particularly shown and described with reference to embodiments thereof, it will be understood by those of ordinary skill in the art that various changes in form and details may be made in the display apparatus of the present disclosure without departing from the technical idea and scope of the present disclosure as defined by the appended claims and their equivalents. Thus, it is intended that the present disclosure cover the modifications and variations of this disclosure provided they come within the scope of the appended claims and their equivalents.

What is claimed is:

1. A display apparatus, comprising:
a display panel including a display area, a first bezel area and a second bezel area, the first bezel area and the second bezel area disposed to face each other, wherein the display area includes pixels and is between the first bezel area and the second bezel area;
a plurality of gate drivers disposed along a first direction in the first bezel area;
a plurality of source drivers disposed along the first direction in the second bezel area;
a plurality of gate clock supply lines disposed to extend in the first direction in the first bezel area, the plurality of gate clock supply lines configured to supply gate clocks to the plurality of gate drivers;
a plurality of gate output link lines extending in a second direction intersecting with the first direction in output link regions of the display area, the plurality of gate output link lines configured to connect gate outputs of the plurality of gate drivers based on the gate clocks to gate lines of the display panel; and
a plurality of gate clock link lines extending in the second direction in clock link regions of the display area, the plurality of gate clock link lines configured to transfer the gate clocks, input from an outside, to the plurality of gate clock supply lines.

2. The display apparatus of claim 1, wherein the plurality of gate clock link lines disposed in the clock link regions of the display area are multi-connected to different positions of a same clock supply line disposed in the first bezel area, and
wherein a gate clock of a same phase is transferred to the same clock supply line disposed in the first bezel area through the multi-connected plurality of gate clock link lines.

3. The display apparatus of claim 1, wherein the plurality of gate clock link lines disposed in the clock link regions of the display area are further connected to a plurality of gate clock input lines disposed to extend in the first direction in the second bezel area.

4. The display apparatus of claim 1, wherein the plurality of gate clock link lines further extend to the second bezel area, and wherein the plurality of gate clock link lines are connected to an external clock source via a conductive film.

5. The display apparatus of claim 1, wherein, in the display area,
one of the clock link regions is disposed between two adjacent output link regions, and
a pixel area is disposed between an output link region and a corresponding clock link region.

6. The display apparatus of claim 1, wherein each of the plurality of gate drivers comprise a plurality of gate units connected to the plurality of gate output link lines,
wherein the plurality of gate output link lines are multi-connected to different positions of a same gate line, and
wherein a gate output of a same phase is supplied to the same gate line through the multi-connected plurality of gate output link lines.

7. The display apparatus of claim 1, wherein, in each of the clock link regions of the display area, a first power line and a second power line are further disposed to extend in the second direction with the plurality of gate clock link lines between the first power line and the second power line.

8. The display apparatus of claim 7, wherein each of the first power line and the second power line is disposed between one of data lines of the display panel and at least one of the plurality of gate clock link lines.

9. The display apparatus of claim 1, wherein the display panel further comprises a notch where a panel resolution in the second direction is relatively less than a normal area,
wherein the plurality of gate drivers are divided into first-group gate drivers disposed at a first side with respect to a center portion of the notch and second-group gate drivers disposed at a second side opposite to the first side with respect to the center portion of the notch, and
wherein a start carry transfer direction for an operation activation of the first-group gate drivers is opposite to a start carry transfer direction for an operation activation of the second-group gate drivers.

10. The display apparatus of claim 9, wherein the start carry transfer direction of the first-group gate drivers is toward a left edge portion of the display panel from the center portion of the notch, and
wherein the start carry transfer direction of the second-group gate drivers is toward a right edge portion of the display panel from the center portion of the notch.

11. The display apparatus of claim 1, wherein each of the plurality of gate output link lines comprises:
a low-resistance link line connected to one of the gate outputs of the plurality of gate drivers; and
a high-resistance link line connected to one of the gate lines of the display panel through a first contact portion and connected to the low-resistance link line through a second contact portion,
wherein a resistance of the low-resistance link line is less than a resistance of the high-resistance link line, and
wherein the low-resistance link line and the high-resistance link line overlap each other with an insulation layer between the low-resistance link line and the high-resistance link line.

12. The display apparatus of claim 11, wherein the low-resistance link line and the high-resistance link line have a same line width.

13. The display apparatus of claim 11, wherein a first gate output link line of the plurality of gate output link lines connects a gate output of a first gate unit to a first gate line of the display panel,
wherein a second gate output link line of the plurality of gate output link lines connects a gate output of a second gate unit to a second gate line of the display panel, and
wherein an interval between the first contact portion and the second contact portion in the second gate output link line differs from an interval between the first contact portion and the second contact portion in the first gate output link line.

14. The display apparatus of claim 13, wherein the interval between the first contact portion and the second contact portion in the second gate output link line is less than the interval between the first contact portion and the second contact portion in the first gate output link line.

15. A display panel, comprising:
a first bezel area and a second bezel area disposed to face each other;
a display area between the first bezel area and the second bezel area, the display area including pixels;
a plurality of gate drivers disposed along a first direction in the first bezel area;
a plurality of source drivers disposed along the first direction in the second bezel area;
a plurality of gate clock supply lines disposed to extend in the first direction in the first bezel area, the plurality of gate clock supply lines configured to supply gate clocks to the plurality of gate drivers;
a plurality of gate output link lines extending in a second direction intersecting with the first direction in output link regions of the display area, the plurality of gate output link lines configured to connect gate outputs of the plurality of gate drivers based on the gate clocks to gate lines of the display panel; and
a plurality of gate clock link lines extending in the second direction in clock link regions of the display area, the plurality of gate clock link lines configured to transfer the gate clocks, input from an outside, to the plurality of gate clock supply lines,
wherein each of the plurality of gate drivers includes a plurality of gate units configured to generate gate outputs of different phases and supply the gate outputs to corresponding gate lines of the display panel.

16. The display panel of claim 15, wherein gate outputs of a same phase are supplied from the plurality of gate drivers to different positions of a same gate line, and
wherein a gate clock of a same phase is transferred to a same clock supply line disposed in the first bezel area through the plurality of gate clock link lines that are multi-connected.

17. The display panel of claim 15, wherein each of the plurality of gate output link lines comprises:
a low-resistance link line connected to one of the gate outputs of the plurality of gate drivers; and
a high-resistance link line connected to one of the gate lines of the display panel through a first contact portion and connected to the low-resistance link line through a second contact portion,
wherein a resistance of the low-resistance link line is less than a resistance of the high-resistance link line, and
wherein the low-resistance link line and the high-resistance link line overlap each other with an insulation layer between the low-resistance link line and the high-resistance link line.

18. The display panel of claim 17, wherein a first gate output link line of the plurality of gate output link lines connects a gate output of a first gate unit to a first gate line of the display panel,
wherein a second gate output link line of the plurality of gate output link lines connects a gate output of a second gate unit to a second gate line of the display panel, and
wherein an interval between the first contact portion and the second contact portion in the second gate output link line differs from an interval between the first contact portion and the second contact portion in the first gate output link line.
